(19) United States
(12) Patent Application Publication
(10) Pub. No.: US 2007/0075784 A1
(43) Pub. Date: Apr. 5, 2007

(54) Radio frequency power amplifier

(76) Inventors: Ola Pettersson, Jarfalla (SE); Andrej Litwin, Danderyd (SE)

Correspondence Address: ESCHWEILER & ASSOCIATES, LLC;NATIONAL CITY BANK BUILDING, 629 EUCLID AVE., SUITE 1000, CLEVELAND, OH, 44114, US

(21) Appl. No.: 11/496,133

(22) Filed: Jul. 31, 2006

Related U.S. Application Data
(63) Continuation of application No. PCT/SE05/00041, filed on Jan. 17, 2005.

(30) Foreign Application Priority Data
Feb. 5, 2004 (SE) SE0400231-7

(51) Int. Cl. H03F 1/22

(52) U.S. Cl. 330/311

(57) ABSTRACT

The present invention relates to a cascode radio frequency power amplifier, including at least two cascaded MOS transistors formed in a mutual substrate, where the bulk nodes of the transistors are isolated from each other and connected to the respective source of each transistor. The present invention also teaches that the drain of the topmost transistor is connected to the power supply through an inductive load, and that the gate of each upper transistor is equipped with a self-biasing circuit connected at least between the drain and the gate of the respective upper transistor.

### REFERENCE TO RELATED APPLICATIONS

This application is a continuation of PCT/SE2005/000041 filed Jan. 17, 2005 which was not published in English, that claims the benefit of the priority date of Swedish Patent Application No. SE 0400231-7, filed on Feb. 5, 2004, the contents of which both are herein incorporated by reference in their entireties.

### FIELD OF INVENTION

The present invention relates to a cascode radio frequency power amplifier, comprising at least two cascaded MOS transistors formed in a mutual substrate.

### BACKGROUND OF THE INVENTION

The ever-increasing market for microwave power amplifiers in wireless systems requires low cost ease of use technology. It has been an increasing interest in designing radio frequency power amplifiers in digital CMOS technology. This follows the trend to integrate a complete transceiver together with the digital baseband part on a single chip. One of the main issues in the design of power amplifiers in submicron CMOS, is the long-term reliability due to the large voltage swing on the power amplifiers output. This swing can exceed the supply voltage by a factor of 2 for class A amplifiers and by as much as a factor of 3.6 for class E amplifiers. If the voltage swing is higher then the maximum allowed drain voltage for the transistors, it may cause the reliability problems by hot electrons that will degrade the device performance or by gate oxide breakdown that will permanently damage it.

There are several different ways to circumvent the problem. Designing a power amplifier at a smaller supply voltage has several drawbacks. In order to get the same output power, the impedance at the output must be reduced by the square value of the supply reduction. That in turn affects negatively the power amplifier performance.

Publications “Novel BiCMOS Compatible, Short Channel LDMOS Technology for Medium Voltage RF & Power Applications”, by A. Litwin, O. Bengtsson and J, Olsson, International Microwave Symposium IMS 2002, Jun. 2-7, 2002, Seattle USA, and “High Performance RF LDMOS Transistors with 5 nm Gate Oxide in a 0.25 μm SiGe:C BiCMOS Technology”, by K.-E. Ehwald et el, IEEE IEDM Tech. Dig, p. 895, 2001, describe specialised device technologies, such as LDMOS, that can handle much higher voltages than CMOS, but they are not readily available in standard CMOS and if so, they require additional process complexity, increasing the cost.

Another solution is to use the cascode configuration that normally will allow higher voltage at the output since the output voltage swing will be divided between the two cascaded transistors, as described in publications U.S. Pat No. 6,496,074, U.S. Pat. No. 6,515,547, and “A 2.4-GHz 0.18 μm CMOS Self-Biased Cascode Power Amplifier” by Tirdad Sowlati et al. IEEE Journal Solid State Circuits, Vol. 38, No. 8, August 2003. Such solution is the most attractive when using conventional CMOS and when reliability issues are of concern.

In prior art radio frequency power amplifier designs, low drift during a shorter period of time has been exhibited. However, the operation of the top cascode transistor is such that the transistor sees a back bias in reference to the substrate, which is typical when using CMOS technology with a common substrate potential. It has been shown elsewhere that such a condition may cause transistor degradation, as can be seen in publication “Enhanced Negative Substrate Bias Degradation in nMOSFETs With Ultra thin Plasma Nitrided Oxide” by Tsu-Hsiu Perng et al. IEEE Electron Device Letters, Vol. 24, No. 5, May 2003, P. 333, and thus create reliability problems. The prior art solution also limits the maximum signal voltage on the output of the amplifier due to the reliability concern, i.e. use of such a cascode amplifier for higher amplifier classes, since they cause a larger voltage swing above the power supply.

Another disadvantage of the prior art is that due to the substrate back bias the gain of the amplifier is reduced, since the source of the upper transistor is elevated to approximately half of the voltage swing of the power amplifier output.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present one or more concepts of the invention in a simplified form as a prelude to the more detailed description that is presented later.

With the purpose of solving one or more of the above-identified problems the present invention comprises a cascode radio frequency power amplifier with isolated transistors. In one embodiment the amplifier comprises isolated MOS transistors, for example, in a triple well option in CMOS bulk technology, or using CMOS on Silicon-on-Insulator, where all transistors are isolated from the substrate.

Connecting the source of each transistor to its well contact in one embodiment of the invention makes the substrate region under the channel follow the source potential. This in turn reduces the voltage over all transistor terminals to acceptable values. It also allows stacking more than two transistors, for example, three or four, to withstand higher voltage on the power amplifier output.

A second advantage of the invention in one embodiment is that the power amplifier gain is increased in the comparison with the prior art, since the bulk back bias effect on the top transistors that increases their threshold voltage is absent.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

A radio frequency power amplifier according to the present invention will now be described in detail with reference to the accompanying drawings, in which:

FIG. 1a is a schematic view of a previously known self-biased cascode amplifier,

FIG. 1b is a graph illustrating voltage waveforms versus time of the previously known cascode amplifier,

FIG. 2a is a schematic view of a single ended cascode amplifier according to one embodiment of the invention,

FIG. 2b is a schematic view of a differential cascode amplifier according to another embodiment of the invention, and

FIG. 3 is a graph illustrating output voltage waveforms at the topmost transistor with and without connection between bulk and source nodes.

### DETAILED DESCRIPTION OF THE INVENTION

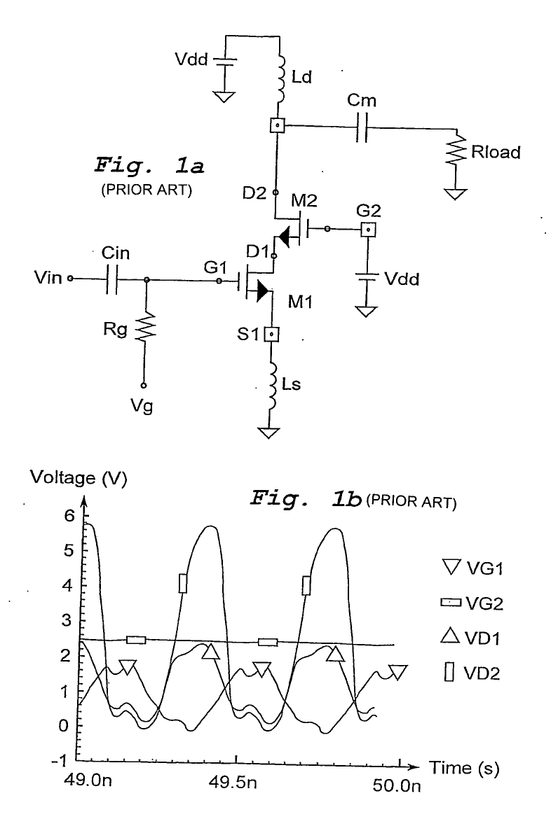

It is, as previously stated, known to use the cascode configuration according to prior art FIG. 1a that normally will allow higher voltage VD2 at the output, as can be seen in prior art FIG. 1b, since the output voltage swing will be divided between the two cascaded transistors M1, M2.

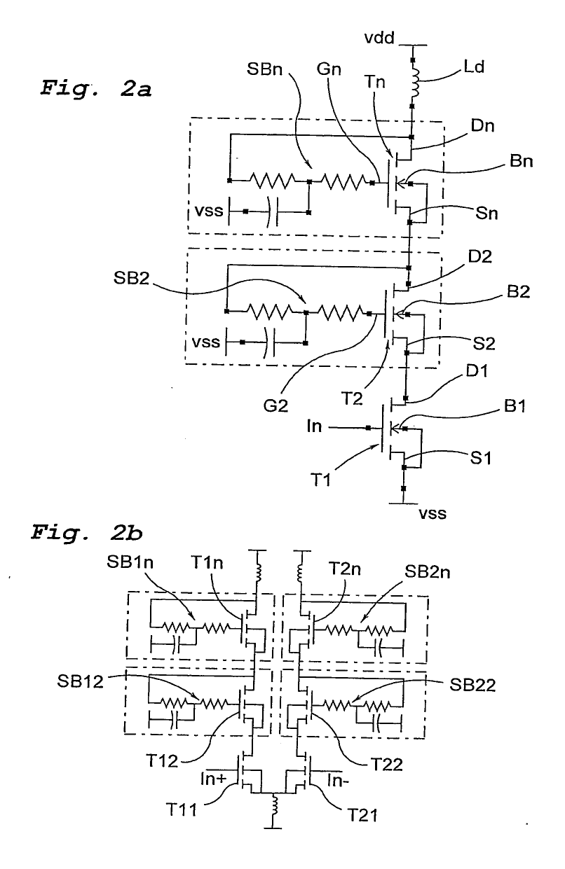

An inventive radio frequency power amplifier in accordance with one embodiment of the invention will now be described with reference to FIG. 2a where an inventive cascode power amplifier PA is implemented with at least two, in the figure three, cascaded MOS transistors T1, T2, Tn formed in a mutual substrate that have the bulk node B1, B2, Bn isolated from each other and connected to the respective source S1, S2, Sn of each transistor T1, T2, Tn.

The present invention teaches that the drain Dn of the topmost transistor Tn is connected to the power supply vdd through an inductive load Ld and that the gates G2, Gn of each upper transistor T2, Tn are equipped with a self-biasing circuit SB2, SBn connected at least between the drain D2, Dn and the gate G2, Gn of respective upper transistor T2, Tn, where each transistor above the first transistor T1 is designated upper transistor, and where the last upper transistor Tn is designated topmost transistor.

It is also proposed that the bulk nodes B2, Bn of at least the upper transistors T2, Tn are isolated from the substrate. The bulk node B1 of the first transistor T1 may also be isolated from the substrate even if this is not required.

One simple way to achieve the desired isolation according to one embodiment of the invention is to use a triple well option in CMOS that isolates the NMOS transistors p-well from the p-bulk, by surrounding it by an additional n-well. That allows one to short circuit the source of each cascode transistor with its well, with the result that the well will follow the source potential.

An alternative way to achieve the isolation between the cascode transistors according to another embodiment of the invention is to use CMOS on Silicon-on-Insulator. The drain-source voltage and gate-bulk voltage will, with such a solution, assume the values acceptable for the used CMOS technology. It also allows stacking more transistors in the cascode to withstanding higher voltage swings in, for example, class E power amplifiers. In this case three steps or transistors in the cascode would be an acceptable option.

In order to achieve the full advantage of the inventive solution, a biasing scheme is proposed in one embodiment that will maximise the gain and will allow for two or more transistors to be stacked. However, other biasing schemes are possible to optimise other power amplifier properties, for example, linearity.

FIG. 2a is a schematic view of an inventive single ended cascode amplifier and FIG. 2b is a schematic view of how the present invention may be applied to form an inventive differential cascode amplifier with six transistors, T11, T12, T1n, T21, T22, T2n, and self-biasing circuits SB12, SB1n, SB21, SB2n belonging to each upper transistor T12, T1n, T22, T2n according to another embodiment of the invention.

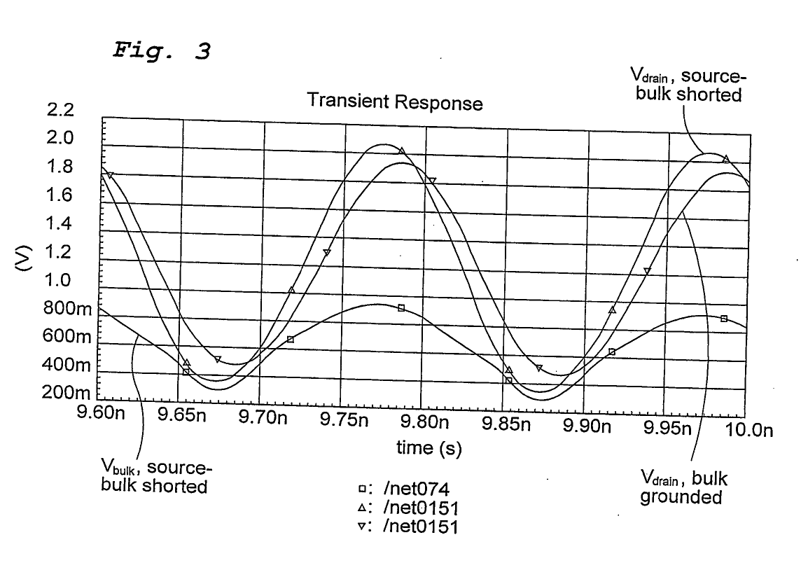

FIG. 3 shows the output voltage waveforms at the top transistor with and without connection between bulk and source nodes. The voltage waveform for the bulk connected to the source is also displayed, corresponding curve for the case with the bulk grounded is zero in this example.

The figure shows that the proposed solution increases the power amplifier gain in the comparison with the prior art, since the bulk back bias effect on the top transistors that increases their threshold voltage is absent.

In addition, while a particular feature or aspect of the invention may have been disclosed with respect to only one of several implementations, such feature or aspect may be combined with one or more other features or aspects of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.” Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

1. A cascode radio frequency power amplifier, comprising:
at least two cascaded MOS transistors formed in a mutual substrate, each comprising bulk nodes, and extending between a topmost transistor and a bottom transistor, and wherein the MOS transistors not including the bottom transistor comprise upper transistors,
wherein the bulk nodes of the transistors are electrically isolated from each other and connected to a respective source of each transistor,
wherein a drain of the topmost transistor is connected to a power supply potential through an inductive load, and
wherein a gate of one or more upper transistors is coupled to a self-biasing circuit connected at least between the drain and the gate of the respective upper transistor.

2. The amplifier of claim 1, wherein each of the upper transistors are coupled to a respective self-biasing circuit.

3. The amplifier of claim 1, wherein the bulk nodes of at least the upper transistors are each isolated from the substrate.

4. The amplifier of claim 1, wherein the transistors comprise triple well CMOS transistors, wherein a well of each respective transistor is isolated from the bulk, and wherein the well of each respective transistor is short circuited to the source thereof.

5. The amplifier of claim 1, wherein the transistors comprise CMOS transistors on a Silicon-on-Insulator substrate, wherein a well of each respective transistor is isolated from a bulk portion of the substrate, and wherein the well of each respective transistor is short circuited to its respective source.

6. The amplifier of claim 1, wherein the transistors and the self-biasing circuits are configured to bias the transistors to force such transistors into predetermined operating regions thereof, thereby maximizing the amplifier gain.

7. The amplifier of claim 1, wherein transistors and the self-biasing circuits are configured to bias the transistors into a linear operating region thereof, thereby optimizing the amplifier linearity.

8. A radio frequency amplifier, comprising:
at least two series connected MOS transistors formed in a mutual substrate and each comprising a bulk node, wherein one of the transistors comprises a topmost transistor and has a terminal coupled to a supply potential through a load, and wherein one of the transistors comprises a bottom transistor and has a terminal coupled to a reference potential, and a control terminal forming an amplifier input,
wherein the bulk nodes of each transistor is coupled to a respective source terminal thereof, and wherein the bulk nodes of at least two of the MOS transistors are electrically isolated from one another.

9. The amplifier of claim 8, further comprising a self-biasing circuit coupled between a drain terminal and a control terminal of at least one of the transistors that is not the bottom transistor.

10. The amplifier of claim 9, wherein each of the transistors, excluding the bottom transistor, has a self-biasing circuit associated therewith coupled between the control terminal and the drain terminal thereof.

11. The amplifier of claim 9, wherein the self-biasing circuit is configured to bias the at least one transistor in a linear operating range thereof.

12. The amplifier of claim 8, wherein the bulk nodes of each of the transistors are electrically isolated from one another.

13. The amplifier of claim 8, wherein the bulk node is coupled to a respective source terminal of each of the transistors.
